(19) United States
(12) Patent Application Publication
(10) Pub. No.: US 2012/0139540 A1
(43) Pub. Date: Jun. 7, 2012

(54) METHOD OF EVALUATING PERFORMANCE CHARACTERISTICS

(76) Inventors: Janine Anne Flood, Cincinnati, OH (US); Vanessa Catherine, Bruxelles (BE); Irma Leticia Espinosa, Middlesex (GB); Guillaume Bonnet, Bruxelles (BE); Mark Steven Hayworth, Cincinnati, OH (US); Thomas Edward Dufresne, Morrow, OH (US); Yong Pan, Covington, KY (US)

(21) Appl. No.: 13/309,015

(22) Filed: Dec. 1, 2011

Related U.S. Application Data
(60) Provisional application No. 61/418,604, filed on Dec. 1, 2010.

(51) Int. Cl. G01R 33/48; G01N 23/04

(52) U.S. Cl. 324/309; 378/62; 378/4

(57) ABSTRACT

A non-destructive method of visualizing penetration of a soil and/or fabric conditioning component in a fabric using imaging techniques. The method may be used to determine qualitatively and/or quantitatively the penetration of soil and/or fabric conditioning component into the fabric. By comparing images before and after fabric treatment processes, the efficacy of a fabric treatment processes can be assessed.

### CROSS REFERENCE TO RELATED APPLICATION

This application claims the benefit of U.S. Provisional Application No. 61/418,604, filed Dec. 1, 2010.

### FIELD OF THE INVENTION

This invention relates to methods for observing the interior of a fabric and to a method for determining the efficacy of a fabric treatment step, particularly a fabric cleaning step, such as an aqueous washing step.

### BACKGROUND OF THE INVENTION

Understanding penetration of soils and fabric treatment components into fabrics can provide useful information about the fabric properties or about the efficacy of fabric treatment steps. A detergent manufacturer may wish to gain a better understanding of soil/stain penetration into a fabric in an effort to obtain a better understanding of how to effectively provide cleaning. In addition, gaining a better knowledge of deposition of fabric treatment components can lead to development of more successful fabric treatment compositions. Prior methods for observing and measuring of this type of penetration are destructive methods requiring sectioning of the samples to be tested. They tend also to be limited because such prior processes tend to be very labour intensive and enable the analysis of only one location at any one time. The samples for analysis in the prior methods must be very small and obtaining any quantitative information is difficult. Such processes also tend to enable the analysis of only highly coloured or easily observed soils. There is a need in the art for a method for observing the penetration of soils and fabric treatment components into fabrics and for a method of observing the effect of treatment steps such as cleaning steps or fabric conditioning steps on fabrics.

EP1900317 discloses abrasive wipes for treating a surface and use of micro-CT to determine the exposed surface of the wipe surface. WO2010/077651 discloses evaluation of surface coatings using scanning electron microscopy. WO2008/021173 discloses a method of observing the absorbancy of an absorbent article using scanning and imaging methods for example, to observe fluid take-up in a diaper in conditions of use.

### SUMMARY OF THE INVENTION

The present invention provides a non-destructive method of visualizing penetration of a soil and/or fabric conditioning component in a fabric comprising: providing a fabric; contacting the fabric with a soil or fabric conditioning component to enable penetration of the soil or fabric conditioning component into the fabric; and providing an image of the fabric with the soil and/or fabric conditioning component with an imaging device. The method may also be used to determine qualitatively and/or quantitatively the penetration of soil and/or fabric conditioning component into the fabric.

In a further aspect of the invention there is provided a method for visualizing efficacy of a fabric treatment step comprising: providing a fabric; optionally contacting the fabric with a soil to enable penetration of the soil into the fabric; providing a first image of the fabric and any soil with an imaging device; then treating the fabric in a fabric treatment step comprising a cleaning step or a fabric conditioning step; providing a second image of the fabric with any soil and/or fabric conditioning component with the imaging device after the fabric treatment step, at least one of the first or second images comprising both (1) fabric and (2) soil or fabric conditioning component; comparing the first and second images to visualize the change in penetration of soil and/or fabric conditioning component as a result of the fabric treatment step. The method may also be used to determine qualitatively and/or quantitatively the efficacy of the fabric treatment step by comparing the penetration of soil and/or fabric conditioning component into the fabric in the first and second images. For example, the quantitative measurement of penetration or the measurement of the efficacy of the fabric treatment step may be made by measurement and comparison (where necessary) of values of depth or volume of penetration, or intensity and/or density of the soil or conditioning component. Measurement of volume and/or intensity is preferred and volume may be most preferred.

In another aspect of the invention the method is for visualizing and/or determining the efficacy of a cleaning step, preferably an aqueous washing step, wherein a first image of the fabric and soil is obtained prior to a washing step and following a washing step a second image of the fabric and soil is obtained, a comparison of the first and second images enabling the soil removal in the wash step to be determined.

In another aspect of the invention the method is for visualizing and/or determining the efficacy of a fabric conditioning step, preferably in an aqueous laundering process, for example, in which a fabric conditioning component penetrates the fabric in a washing step or in a rinse step, wherein a first image of the fabric is obtained prior to the fabric conditioning step and following the fabric conditioning step, a second image of the fabric and deposited fabric conditioning component is obtained, a comparison of the first and second images enabling the efficacy of deposition of the fabric conditioning component to be determined.

### BRIEF DESCRIPTION OF THE DRAWINGS

FIG. 1 illustrates a plot of Micro-CT depth profile data on stain and fabric density distributions for a tinted moisturizer make-up soil on fabric, before and after an aqueous washing step using a commercially available laundry washing powder detergent. The mean density distribution grey level (x-ray CT density) is shown on the y axis and the depth through fabric (%) on the x axis for a knitted cotton fabric soiled (X2) with the tinted moisturizer make-up. The solid line represents the results before laundering and the broken line represents the results after laundering in an aqueous washing step using a commercially available detergent.

FIG. 2 illustrates Micro-CT images showing x-ray density grey scale images showing depth profile (side view) of knitted cotton fabric and bacon grease stain before (upper) and after (lower) an aqueous washing step using a commercially available laundry washing powder.

FIG. 3 is an MRI image showing a depth profile (side view of fabric) of unsoiled, untreated fabric (i.e. a clean original starting material).

FIG. 4 is an MRI image showing a depth profile (side view of fabric) of bacon grease-soiled fabric.

FIG. 5 is an MRI image showing a depth profile (side view of fabric) of bacon grease-soiled fabric washed in an aqueous washing step using a commercially available washing powder.

FIG. 6 illustrates a plot of MRI mean intensity data on the y axis against region of interest depth profile (%) on the x axis, illustrating the location and degree of bacon grease soil in fabric, taken from before and after laundering in an aqueous washing step using a commercially available washing powder, in comparison to the clean original, unsoiled fabric. The dotted line represents unstained fabric, the broken line represents stained fabric before a washing step and the solid line represents stained fabric after an aqueous washing step.

### DETAILED DESCRIPTION OF THE INVENTION

Unless otherwise stated all percentages are on a weight basis.

The fabric treatment step is a cleaning and/or fabric conditioning step. Typically, though not always, the cleaning or fabric conditioning step comprises contacting the fabric with a cleaning composition or fabric conditioning composition in a pre-treat, wash or rinse step. Preferred fabric treatment steps are in aqueous liquor.

Suitable detergent compositions/fabric conditioning compositions may be in any form known in the art suitable for delivering a cleaning or fabric conditioning component to a fabric, for example, solid, liquid or gel form. Examples include pre-treatment compositions, washing additives, rinse-added compositions or fully formulated detergents. Suitable compositions include granular detergent compositions, tablets, liquigel optionally in unit dose form, such as in pouches or pillows, generally comprising water soluble film containing liquigel detergent.

Preferably the fabric treatment step is part of an aqueous cleaning and/or fabric conditioning step, for example as part of a hand washing or machine washing process. In a fabric washing process, fabric is contacted with water, preferably in combination with a detergent composition. In a fabric conditioning step, the fabric is contacted with a fabric conditioning component or composition, preferably in aqueous solution, either in a washing step, for example as part of a detergent composition or in a post-washing rinse step.

Fabric conditioning compositions suitable for use in the present invention may be added through the wash, so that the fabric conditioning component is present during the wash process and/or rinse process. Alternatively, the fabric conditioning component is contacted with the fabric in a rinse step, as such rinse-added fabric conditioning steps tend to be more effective in deposition of fabric conditioning components. Alternatively, they may be contacted with the fabric during a drying step, spray-on step, soak step or ironing step.

By non-destructive is meant that the fabric sample remains intact whilst the image of the fabric with or without soil or conditioning component is taken, to get information from within the fabric, i.e within the fibres, or in the z direction. In contrast, in the prior art destructive processes, a sample is cut for observation to expose a cross-cut face to take data from that cross-cut face.

By penetration within the fabric or into the fibres of the fabric, it is intended to refer to penetration of the soil and/or fabric conditioning component into the fibres, either inter-fibre, so that penetration is below the first layer of fibres at least, for example between a first layer of fibres and a second layer of fibres; and/or intra-fibre so that penetration is inside the fibres themselves. The fibres may be multifilament (such as natural fibres and mixed natural/synthetic fibres such as wool, cotton, polycotton) or single filament, such as manmade fibres, for example, nylon and polyester.

In a preferred embodiment, soil penetration in the fabric samples is measured both before and after a laundry washing treatment step. Any washing or drying conditions may be selected and the present invention may also be used to determine the effect of external factors such as water hardness, temperature, duration, type of machine, rinse conditions, amount of fabric and soil per load, pre-dissolution of detergent, etc on the efficacy of the fabric treatment step.

The image of the fabric with any soil and/or fabric treatment composition is provided demonstrating the presence or absence of soil and/or fabric conditioning component using scanning and imaging equipment. The image can be 2-dimensional or 3-dimensional, or a compilation of several images, or a rendering, or a hologram.

The image of the fabric and any soil and/or fabric conditioning component may be generated by any suitable imaging or scanning technique. Examples include MRI (Magnetic Resonance Imaging), magnetic resonance force microscopy (MRFM), x-ray computed tomography (CT) scanning, multiphoton microscopy, CLSM (Confocal Laser Scanning microscopy), and Raman microscopy (including Confocal Raman, CARS (Coherent anti-Stokes Raman Scattering) and SRS (Stimulated Raman Scattering)). Particularly preferred imaging techniques are those that do not require labeling, so that unlabelled soil and/or fabric conditioning component are detected. Preferred imaging and scanning techniques are Confocal Raman, reflectance CLSM, CARS, SHG, SRS, as well as MRI, MRFM, and CT, including microCT and nanoCT. The techniques MRI and CT scanning are more preferred, CT being most preferred. Preferred techniques for use in the invention are unlabelled techniques, ie. the image can be created whilst the sample is in its natural state. Labelling techniques will be well-understood by the skilled person, typically, dyes, pigments, radio labels, isotope labels, fluorescence or particle traces are used to enable images to be created.

Preferred image recording means for use with the imaging instruments for use in the present invention are typically monochromatic and are capable of generating projection images in bit depth of at least 8, or even at least 12 or preferably at least 16 or even more preferably greater than 16 or even greater bit depth such as above 20 or 30 typically associated with multiple channels such as multiple spectral or multiple colour or multiple chemical channels, to discriminate a large number of different X-ray absorption levels. Devices capable of sub-micrometer resolution are preferred as this enables greater clarity of images and therefore, greater quantitative precision, even for small features.

### MRI

A preferred imaging method is MRI. Many MRI instruments are made of a horizontal tube that runs through a main magnet. The main magnet can be any suitable magnet. Some examples include a permanent magnet, a superconducting magnet, etc. The main magnet may be in the range from approximately 0.5 tesla to 4.7 tesla, or any individual number within that range. An MRI machine also may include one or more gradient magnets, which may be of relatively low strength compared to the main magnet. In one example, three gradient magnets are used. When a fabric sample is placed in the tube of the MRI machine, the main magnet immerses the fabric sample in a stable and intense magnetic field and the gradient magnets create a variable field. Preferred MRI imaging may include taking MRI images and using spin echo pulse sequence with Imaging (RF) coil, or rapid acquisition with relaxation enhancement (RARE), or three dimensional (3D) visualization including the use of multi-slice multi-echo (MSME), or magnetic resonance force microscopy (MRFM), or other techniques or subsets or combinations of the above. RARE is a pulse sequence which can be used to collect two-dimensional (2D) MRI images that allow a user to observe dynamics in real-time, and is sometimes referred to as turbo spin echo, or TSE, or fast spin echo, also known as FSE. RARE is commercially available from for example, Bruker Instruments, Billerica, USA. MSME is a collection of slices that can be re-sliced to any plane and rendered as 3D surfaces or volumes. Magnetic resonance force microscopy (MRFM) may be used in the present invention to provide extremely high resolution, preferably below 100 nanometers, more preferably below 50 or 10 or 5 or even more preferably four nanometers or below. In a preferred embodiment, magnetic forces are detected by MRFM via a microscopic silicon cantilever while the sample interacts with a fine magnetic tip. Movement and vibrations of the cantilever are tracked by laser interferometry. Scanning the tip across the sample in three dimensions can be used to create a 3 dimensional (3D) image. A suitable instrument may be obtained from IBM Labs.

In a preferred embodiment, a method is provided for measuring by MRI, the 3-dimensional nature of soiling in fabric and the efficacy of detergents for removing the soil. Changes in atomic magnetic field rotations resulting from the presence of certain soils or treatments can be quantified via MRI. For example, by examining the signal intensity distribution through the fabric, it is possible to have an understanding of the profile of the soil, or the residual soil after washing.

For example, the invention may be used to visualize soil, soil removal and/or deposition of a fabric conditioning component. The present invention has been found to particularly useful in visualizing or measuring deposition and removal of oily soils, such as oily food soils or oily body soils and/or oily make-up soils. Any fabric sample is suitable for use in the present invention. In a preferred embodiment of the invention 2D images are taken through the fabric samples. The 2D slices are then reconstructed into a 3D data set. Image analysis is then run on the 3D data set. In a preferred method of the invention, the distribution of soil and/or conditioning component is determined by the following steps: (a) selecting a fixed Region of Interest (ROI) which includes the full thickness of the fabric. (fiduciary marks may optionally also be used to indicate the top and bottom fabric surfaces); (b) creating depth masks from the top and bottom of the fabric or ROI; (c) smoothing the depth maps using an iterative median filter; (d) taking, for each X/Y coordinate, the top and bottom depth map at this point, to represent the min and max Z values, respectively that represent the top and bottom surfaces, respectively; (e) normalizing all points in between the top and bottom to 0-100%; (f) calculating the mean value of every normalized point in X/Y that has the same percentage (e.g., find all values in the image that are at 1% and obtain the mean grey level value); and (g) plotting the resulting intensity distribution, and optionally comparing soil before and after laundering. Alternatively or in addition, a comparison can also be made of conditioning agent before and after fabric conditioning.

microCT

In a preferred aspect of the invention, the images are generated using micro-CT. In accordance with this non-destructive test method, the sample specimen is irradiated with X-rays. The radiation transmitted through the sample is collected into an X-ray scintillator to transform the X-rays into electromagnetic radiations detectable by the camera. The obtained 2D image is also called a projected image or shadow image. In order to visualize or measure penetration for a 3D volume of the fabric sample, a plurality of the projected images is preferred. The X-ray absorption specific for each of the volume elements (voxels) located along the transmission lines of the X-rays radiated from the source through the sample to the camera are determined. Several projected images are taken from different angles to enable a reconstruction of 3D space. The sample specimen is thus rotated (either 180° or 360°) and new data gathered after each change in rotation angle. Preferably, during the imaging, data is gathered after multiple small rotation steps; the smallest possible rotation steps giving the greatest precision. Additional corrections eliminate the positive blur in the back projection process and the distortions induced by the cone beam geometry associated with using a 2D detector.

In one aspect of the invention, images are provided using high resolution X-ray micro-tomography. Preferred instruments include those that enable spatial resolution below 400 nm, or even below 300 or 250 nm. Suitable devices for use in the present invention include nano-tomography X-ray instruments from Skyscan (Kontich, Belgium), for non-destructive 3D microCT imaging preferably with a spatial resolution of about 400 nanometers or below. Another suitable instrument is the UltraXRM microCT X-ray instrument from Xradia (Concord, Calif., USA) which uses advanced synchrotron based X-ray optics to achieve a 3D volumetric resolution of less than 200 or even less than 100 nanometers. In some 2D detectors it is possible to reconstruct 100 or even 200 slices or more, simultaneously with a Field Of View/Resolution ratio of preferably greater than 1000 or more preferably greater than 2000 (e.g. 6 μm resolution at 12 mm Field of View size). Preferred 3D datasets are saved as 8 bit images (256 gray levels), or greater for example 16 bit images or greater.

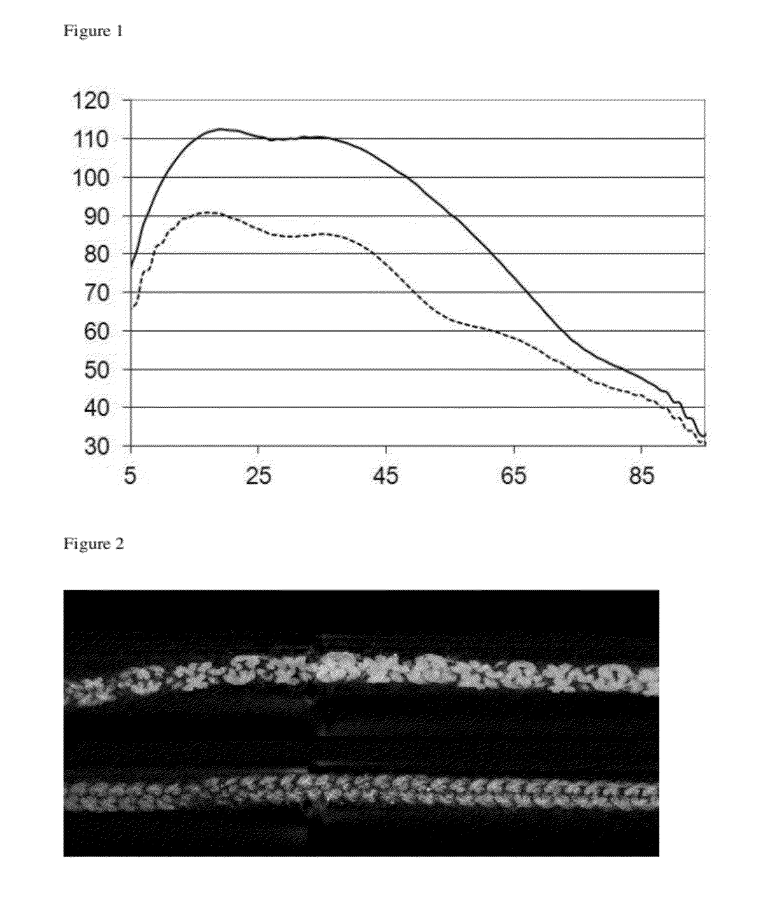

In one embodiment, a microCT method has been developed for examining the 3-dimensional nature of fabric soiling and the efficacy of detergents for removing the soils and/or fabric conditioning agent deposition. Changes in density caused by the presence of certain soils or treatments can be quantified via microCT. By examining the distribution of density (microCT grey level intensity) at various locations through the fabric, it is possible to have an understanding of the penetration profile of the soil and/or fabric conditioning component. Comparing data from multiple images can reveal the relative performance in stain removal after washing or conditioning. In the examples of FIGS. 1 and 2, density data obtained by microCT (x-ray tomography), of tinted facial moisturizer soil and bacon grease soil on knitted cotton fabric, are shown displayed as a graph or a 2D image slice, respectively.

In a preferred embodiment of the invention, a fabric swatch is placed in a sample holder, held in place with adhesive tape, and placed in a Micro-CT scanner such as the Scanco MicroCT40 x-ray scanner (Scanco Medical, Zurich, Switzerland The sample is rotated through 360°, the rotating step is preferably below 1°, most preferably below 0.5°. or even below 0.2°. The lowest energy X-rays are preferably filtered, for example through aluminium. In a preferred embodiment of the invention, at least 500 or even at least 750 or even at least 1000 projections are used to create a 3D data set with a bit-depth of at least 8 or 12 or even at least 16 bits/voxel. Preferably, noise smoothing is set as low as possible. An image analysis program is then run. In a preferred embodiment the algorithm to find the distribution has the following steps: (a) selecting a threshold value which includes at least 50%, preferably at least 80% or even 90 or 95% of the fabric fibres; (b) using the fixed threshold value to determine a depth mask from the top and bottom; (c) smoothing the depth maps using an iterative median filter; (d) for each X/Y coordinate, the top and bottom depth map at this point, represent the min and max Z values that represent the top and bottom surfaces, respectively; (e) normalizing all points in between the top and bottom to 0-100%; (f) calculating the mean value of every normalized point in X/Y that has the same percentage (e.g. find all values in the image that are at 1% and obtain the mean grey level value); and (g) plotting the resulting intensity distribution, and if desired, comparing soiled fabric before and after laundering or conditioning.

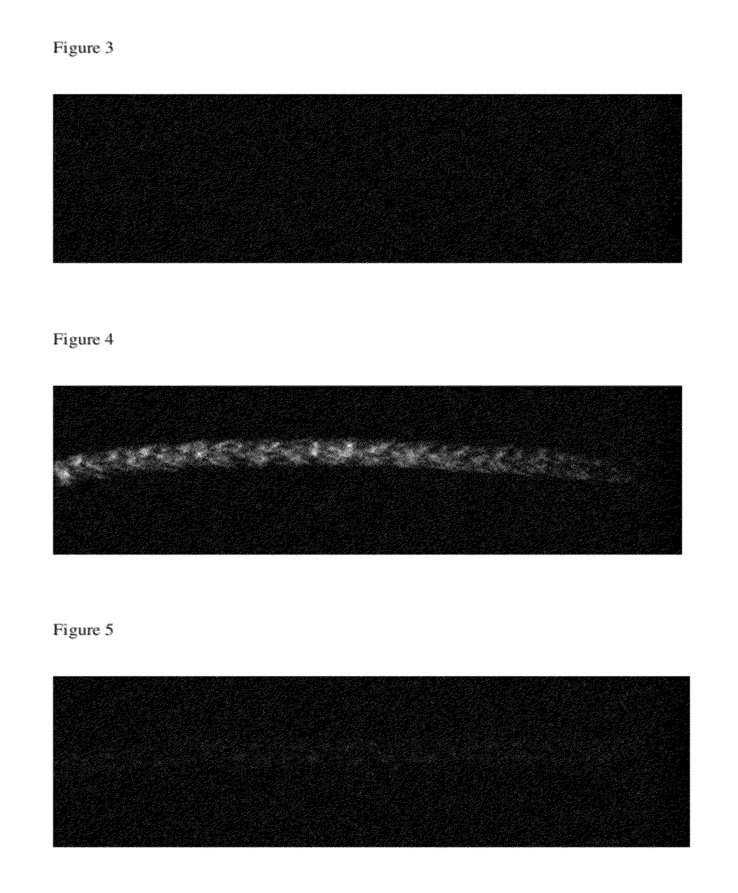

The information obtained in accordance with the invention may be in any desired form, including a slice, a series of slices, an image, a rendering, a hologram, a projection, a data file, a graph, a chart, a data table, wave form, electronic, etc. In one embodiment the data is visualized using 2 dimensional (2D) slices. The data of the 2D slice may be presented in any desired format. In the example of FIGS. 3, 4, 5 and 6, data obtained by spin echo pulse sequence MRI, are shown displayed as a 2D image slice or graph. Several 2D slices can be used to create a 3 dimensional (3D) image or 3D data set. Suitable slices may be from 4 nanometers thick to 24 cm, or the information may be captured at any desired or suitable spatial interval, for example from 100 nm to 1000 microns, or even from 200 nm to 250 microns, or 400 nm to 500 microns thick. Images of greater pixels (2D) or voxels (3D) give greater clarity and precision for quantitative measurements and are therefore preferred.

Three dimensional data sets may typically comprise from around 100 two dimensional slices which are closely spaced or contiguous. In some embodiments, the 2D slices are each about 500 nanometers thick.

The visual images can be used to measure or illustrate the penetration of soil and/or fabric conditioning component into fabric, and can be used to determine efficacy of fabric cleaning or conditioning steps. For a fabric cleaning step, soiled fabric undergoes a cleaning step and images from before and after cleaning are compared. A comparison of the images before and after the cleaning step gives a visual, qualitative indication of the soil removal. A comparison of depth or volume of soil and/or intensity or density of soil gives a quantitative indication of soil removal. For a fabric conditioning step, untreated fabric undergoes a fabric conditioning step and images from before and after fabric conditioning are compared. A comparison of the images before and after the conditioning step gives a visual, qualitative indication of the deposition of the conditioning component. A comparison of depth of conditioning component and/or intensity gives a quantitative indication of effective fabric conditioning.

In a preferred embodiment of the invention, micro-CT is used to visualize the penetration of the soil and/or fabric conditioning component into the fibres of the fabric.

Typically, solid detergent compositions are fully formulated laundry detergent compositions. Typically, the composition comprises a plurality of chemically different particles, such as spray-dried base detergent particles and/or agglomerated base detergent particles and/or extruded base detergent particles, in combination with one or more, typically two or more, or three or more, or four or more, or five or more, or six or more, or even ten or more particles selected from: surfactant particles, including surfactant agglomerates, surfactant extrudates, surfactant needles, surfactant noodles, surfactant flakes; builder particles, such as sodium carbonate and sodium silicate co-builder particles, phosphate particles, zeolite particles, silicate salt particles, carbonate salt particles; polymer particles such as cellulosic polymer particles, polyester particles, polyamine particles, terephthalate polymer particles, polyethylene glycol polymer particles; aesthetic particles such as coloured noodles or needles or lamellae particles, and soap rings including coloured soap rings; enzyme particles such as protease prills, lipase prills, cellulase prills, amylase prills, mannanase prills, pectate lyase prills, xyloglucanase prills, bleaching enzyme prills, cutinase prills and co-prills of any of these enzymes; bleach particles, such as percarbonate particles, especially coated percarbonate particles, such as percarbonate coated with carbonate salt, sulphate salt, silicate salt, borosilicate salt, or any combination thereof, perborate particles, bleach catalyst particles such as transition metal bleach catalyst particles, or oxaziridinium-based bleach catalyst particles, pre-formed peracid particles, especially coated pre-formed peracid particles, and co-bleach particles of bleach activator, source of hydrogen peroxide and optionally bleach catalyst; filler particles such as sulphate salt particles; clay particles such as montmorillonite particles or particles of clay and silicone; flocculant particles such as polyethylene oxide particles; wax particles such as wax agglomerates; brightener particles; dye transfer inhibitor particles; dye fixative particles; perfume particles such as perfume microcapsules, especially melamine formaldehyde-based perfume microcapsules, starch encapsulated perfume accord particles, and pro-perfume particles such as Schiff base reaction product particles; bleach activator particles such as oxybenzene sulphonate bleach activator particles and tetra acetyl ethylene diamine bleach activator particles; hueing dye particles; chelant particles such as chelant agglomerates; and any combination thereof.

Any conventional liquid or liquigel compostions may be used in a cleaning step.

Detergent ingredients suitable for incorporation in the detergent compostions include: detersive surfactants including anionic detersive surfactants, non-ionic detersive surfactants, cationic detersive surfactants, zwitterionic detersive surfactants, amphoteric detersive surfactants, and any combination thereof; polymers including carboxylate polymers, polyethylene glycol polymers, polyester soil release polymers such as terephthalate polymers, amine polymers, cellulosic polymers, dye transfer inhibition polymers, dye lock polymers such as a condensation oligomer produced by condensation of imidazole and epichlorhydrin, optionally in ratio of 1:4:1, hexamethylenediamine derivative polymers, and any combination thereof; builders including zeolites, phosphates, citrate, and any combination thereof; buffers and alkalinity sources including carbonate salts and/or silicate salts; fillers including sulphate salts and bio-filler materials; bleach including bleach activators, sources of available oxygen, pre-formed peracids, bleach catalysts, reducing bleach, and any combination thereof; chelants; photobleach; hueing agents; brighteners; enzymes including proteases, amylases, cellulases, lipases, xylogucanases, pectate lyases, mannanases, bleaching enzymes, cutinases, and any combination thereof; fabric softeners including clay, silicones, quaternary ammonium fabric-softening agents, and any combination thereof; flocculants such as polyethylene oxide; perfume including starch encapsulated perfume accords, perfume microcapsules, perfume loaded zeolites, schif base reaction products of ketone perfume raw materials and polyamines, blooming perfumes, and any combination thereof; aesthetics including soap rings, lamellar aesthetic particles, geltin beads, carbonate and/or sulphate salt speckles, coloured clay, and any combination thereof: and any combination thereof.

Fabric conditioning compositions may be in any form for example, solid or liquid, or for example where they may be added in a drying step, for example on a dryer sheet or other means of dispensing during a drying step. The fabric conditioning component can be any component that improves fabric properties and that provides a consumer noticeable effect. Examples are components that improve fabric feel, integrity, colour, stain repellency, anti-wrinkle properties or even perfume. Perfume may be added directly into the composition or may be added in an encapsulated form, such as perfume microcapsules, such as those encapsulated in melamine-formaldehyde capsules. Suitable components for use in the perfume mixtures, are described in “Perfume and Flavor Chemicals (Aroma Chemicals) by Steffen Arctander. The perfume is preferably present in an amount from 0.001 to 10 wt % of the total weight of the composition.

Suitable fabric conditioning components are generally cationic surfactants and/or silicones.

Cationic surfactant conditioning components are generally quaternary ammonium fabric softening materials with two C12-18 alkyl or alkenyl groups connected to the nitrogen head group, preferably by at least one ester link, or more preferably the quaternary ammonium component has two ester links. Examples are: dialkenyl esters of triethanol ammonium methyl sulphate; C10-20 and C16-18 unsaturated fatty acid reaction products with triethanolamine dimethyl sulphate quaternised; bis(tallowoyloxy)-3-trimethylammonium propane chloride and other examples disclosed in U.S. Pat. No. 4,237,180.

Typical silicones for use in the compositions useful for fabric treatment steps are siloxanes. These may be linear or cyclic. Preferred examples are siloxanes such as poly di-C1-6 alkyl siloxane. Particularly preferred is a (preferably) cyclic polydimethyl siloxane. Suitable examples are available from Dow Corning, such as DC245. DC246, DC1184 and DC347. Silicones may be present in the fabric conditioning composition either directly or pre-emulsified with for an emulsifier such as cationic or nonionic emulsifiers.

Typically liquid carriers may be employed, for example water or mixtures of water and a low molecular weight (e.g. <100) organic solvent, e.g. a lower alcohol. Co-active softeners for the cationic surfactant may also be present such as fatty esters, or fatty N-oxides, or oily sugar derivatives (e.g. as described in WO01/46361). Preferred fatty esters include fatty monoestes such as glycerol monostearate (GMS). Other optional ingredients may be polymeric viscosity control agents, nonionic or cationic polymers, nonionic softeners, bactericides and soil-release agents, pH buffering agents, perfume carriers, fluorescers, colourants, hydrotropes, antifoaming agents, antiredeposition agents, polyelectrolytes, enzymes, optical brightening agents, pearlescers, anti-shrinking agents, anti-wrinkle agents, anti-spotting agents, antioxidants, sunscreens, anti-corrosion agents, drape-imparting agents, preservatives, anti-static agents, ironing aids and other dyes.

Every document cited herein, including any cross referenced or related patent or application, is hereby incorporated herein by reference in its entirety unless expressly excluded or otherwise limited. The citation of any document is not an admission that it is prior art with respect to any invention disclosed or claimed herein or that it alone, or in any combination with any other reference or references, teaches, suggests or discloses any such invention. Further, to the extent that any meaning or definition of a term in this document conflicts with any meaning or definition of the same term in a document incorporated by reference, the meaning or definition assigned to that term in this document shall govern.

While particular embodiments of the present invention have been illustrated and described, it would be obvious to those skilled in the art that various other changes and modifications can be made without departing from the spirit and scope of the invention. It is therefore intended to cover in the appended claims all such changes and modifications that are within the scope of this invention.

### EXAMPLES

### Example 1

A method has been developed for measuring by x-ray CT, the 3-dimensional nature of soiling in fabric and the efficacy of detergents for removing the soil. Changes in density caused by the presence of certain soils or treatments can be quantified via microCT. By examining the distribution of density through the fabric, it is possible to have an understanding of the profile of the stain or the residual stain after washing.

Standardized stained fabric test swatches (multi-stain monitors) were obtained from Warwick Equest Ltd. (Consett, County Durham, UK). These soiled fabrics included knitted cotton fabrics, stained with single dose bacon grease soil or double dose tinted moisturizer makeup (Clinique™) soil. Soil penetration in the fabric samples was measured both before and after a laundry washing treatment step. This laundering step was conducted in a defined and reproducible manner, using Ariel™ laundry detergent according to the manufacturers instructions, and consumer habits.

Fabric was cut into an approximately 5 cm square, wrapped over the top of the sample holder, held in place with adhesive tape, and placed in the Scanco MicroCT40 x-ray scanner (Scanco Medical, Zurich, Switzerland). Scanning parameters were set such that the peak voltage of the X-ray source is 35 kVp, the source current was 180 μA, the projection matrix was 2048×212 pixels, the pixel size was 18 μm, the sample rotation cycle was 360°, the rotating step was 0.18°, the beam exposure time at each rotating step was 300 ms, the frame averaging for signal-to-noise improvement was 10. The lowest energy X-rays are filtered through 0.5 mm of Aluminium. Using 1000 projections to reconstruct, a 3D data set was created that has an approximate size of 2048×2048×209, with a bit-depth of 16 bits/voxel. This was then converted to 8 bit using a scaling factor of 0.05. The pixel size was maintained at 18 μm. Noise smoothing was set as low as possible. Additional post-processing ring artifacts reduction was not required or set to minimum. No X-ray beam hardening correction was required on low X-ray absorbing material or set to minimum. Image analysis was then run on the 3D data set using Matlab R2008a from Mathworks (Natick, Mass., USA), a on a Linux, RedHat Enterprise 4 workstation (Raleigh, N.C., USA). The algorithm to find the density distribution had the following steps:
a. A threshold value which includes the majority of fabric fibres was selected.
b. The fixed threshold value was used to determine a depth mask from the top and bottom.
c. The depth maps were smoothed using an iterative median filter.
d. For each X/Y coordinate, the top and bottom depth map at this point, represent the min and max Z values that represent the top and bottom surface.
e. All points in between the top and bottom were normalized to 0-100%.
f. The mean value of every normalized point in X/Y that has the same percentage was calculated (e.g., find all values in the image that are at 1% and obtain the mean grey level value).
g. The resulting intensity distribution was plotted, and soiled fabrics before and after laundering were compared.

Example results from this method are shown in FIG. 1 which shows the density distribution plot of tinted moisturizer makeup soil (Clinique™) normalized to the percentage of depth through the fabric. The Y-axis shows the MicroCT average intensity grey level value at that location. The two lines together on the graph shows the relative improvement in soil removal after laundry washing with Ariel™ detergent. More example results from this method are shown in FIG. 2 which shows density distribution images in 2D depth profile through the thickness of fabric soiled with bacon grease, before and after laundering

### Example 2

A method has been developed for measuring by MRI, the 3-dimensional nature of soiling in fabric and the efficacy of detergents for removing the soil. Changes in atomic magnetic field rotations resulting from the presence of certain soils or treatments can be quantified via MRI. By examining the signal intensity distribution through the fabric, it is possible to have an understanding of the profile of the soil, or the residual soil after washing.

Standardized stained fabric test swatches (multi-stain monitors) were obtained from Warwick Equest Ltd. (Consett, County Durham, UK). These soiled fabrics included knitted cotton fabrics, stained with single dose bacon grease soil. Soil penetration in the fabric samples is measured both before and after a laundry washing treatment step. This laundering step was conducted in a defined and reproducible manner, using Ariel™ laundry detergent according to the manufacturers instructions, and consumer habits. Fabric samples were obtained from the test swatches by using a 20 mm arch punch. The 20 mm fabric sample were prepared for non-destructive MRI measurements by being placed in a clean and dry glass vial. A sample-containing vial was centered in a 25 mm Imaging Coil (RF coil) on a DMX500 Wide Bore magnet MRI Instrument from Bruker Instruments (Billerica, USA) with a micro 2.5 probe. Using a soiled or conditioned fabric sample, (not a clean, untreated fabric sample), the resonance frequency was set first with a single-pulse experiment every second, centering the highest peak in the centre of the field, using the highest signal in the sample. Data were collected using a spin echo pulse sequence with the power level set to create a 90 degree pulse. Instrument configuration was set to generate proton density weighted images by setting the recycle time (TR) to a value longer than the spin lattice relaxation time (T1) of the soil or conditioning material and the Echo Time (TE) to a value shorter than the spin-spin relaxation time (T2) of the soil or conditioning material. Signal gain was set such that the soiled or conditioned fabric sample results in a digital filling value between 50% and 70%. Forty two slices were obtained at a thickness of 500 nanometers per slice, a field of view (FOV) of 24 mm×6 mm, and with an x-y resolution of 47 micrometers per pixel. Instrument conditions were kept constant all samples within a comparison set, (example: for before and after washing of fabric with a given soil). The 2D slices were then reconstructed into a 3D data set via the Brucker MRI instrument software. Image analysis was then run on the 3D data set using Matlab R2008a from Mathworks (Natick, Mass., USA), on a Linux, RedHat Enterprise 4 workstation (Raleigh, N.C., USA). The algorithm to find the distribution had the following steps:
a. A Region of Interest (ROI) which includes the full thickness of the fabric was selected.
b. Depth masks from the top and bottom of the fixed ROI were created.
c. The depth maps were smoothed using an iterative median filter.
d. For each X/Y coordinate, the top and bottom depth map at this point, represent the min and max Z values that represent the top and bottom surface.
e. All points in between the top and bottom were normalized to 0-100%.
f. The mean value of every normalized point in X/Y that has the same percentage was calculated (e.g., find all values in the image that are at 1% and obtain the mean grey level value).
g. The resulting intensity distribution was plotted, and soiled fabric before and after laundering was compared.

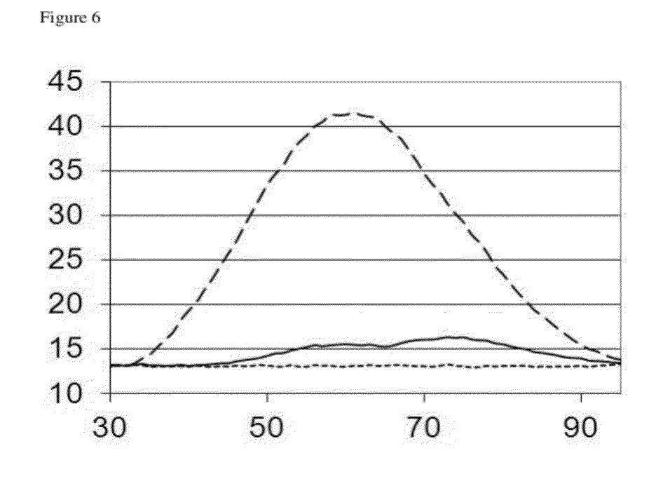

Example results from this method are shown in FIGS. 3, 4, and 5 which show density distribution images in 2D depth profile through the thickness of fabric soiled with bacon grease, before and after laundering More example results from this method are shown in FIG. 6 which shows the density distribution plot for bacon grease soil in knitted cotton fabric, normalized to the percentage of depth through the fabric. The Y-axis shows the MRI average intensity grey level value at that location. The multiple line plots together on the graph show the relative improvement in soil removal after laundry washing with Ariel™ detergent.

Every document cited herein, including any cross referenced or related patent or application, is hereby incorporated herein by reference in its entirety unless expressly excluded or otherwise limited. The citation of any document is not an admission that it is prior art with respect to any invention disclosed or claimed herein or that it alone, or in any combination with any other reference or references, teaches, suggests or discloses any such invention. Further, to the extent that any meaning or definition of a term in this document conflicts with any meaning or definition of the same term in a document incorporated by reference, the meaning or definition assigned to that term in this document shall govern.

While particular embodiments of the present invention have been illustrated and described, it would be obvious to those skilled in the art that various other changes and modifications can be made without departing from the spirit and scope of the invention. It is therefore intended to cover in the appended claims all such changes and modifications that are within the scope of this invention.

What is claimed is:

1. A non-destructive method of visualizing penetration of a component in a fabric comprising the steps of:
i) providing a fabric;
ii) contacting the fabric with a component to enable penetration of the component into the fabric; and
providing a first image of the fabric with the penetrated component with an imaging device, wherein the component is at least one of a soil component and a conditioning component.

2. The method according to claim 1 comprising the additional step of measuring the penetration of the soil and or fabric treatment component.

3. The method according to claim 2 wherein the first image is used to determine the penetration of the soil and/or fabric treatment component into the fabric quantitatively.

4. The method according to claim 1 wherein the first image comprises fabric and a soil.

5. The method according to claim 1 wherein the fabric is contacted with a fabric conditioning component.

6. The method according to claim 1 wherein the imaging device is a magnetic resonance imaging machine.

7. The method according to claim 1 wherein the imaging device comprises an X-ray machine.

8. The method according to claim 1 wherein the imaging device uses computed tomography.

9. The method according to claim 1 wherein the imaging device uses micro or nano-CT tomography.

10. A method for visualizing efficacy of a fabric treatment step comprising:
i) providing a fabric;
ii) optionally contacting the fabric with a soil to enable penetration of the soil into the fabric;
iii) providing a first image of the fabric and any soil on the fabric with an imaging device;
iv) then treating the fabric in a fabric treatment step comprising at least one of a cleaning step or a fabric conditioning step;
v) providing a second image of the fabric with the imaging device after the fabric treatment step; and
vi) comparing the first and second images to visualize the change as a result of the fabric treatment step.

11. The method according to claim 10 wherein the method is used to determine qualitatively and/or quantitatively the efficacy of the fabric treatment step wherein the method comprises comparing estimated or measured values for the penetration of soil and or fabric conditioning component into the fabric in the first and second images to provide an estimated or measured value of the change in soil and or fabric treatment component as a result of the fabric treatment step.

12. The method according to claim 11 wherein the penetration is measured and the method is used to provide a quantitative measure of the change in depth of penetration as a result of the fabric treatment composition.

13. The method according to claim 10 wherein the fabric treatment step is a fabric conditioning step and comparing first and second images is used to visualize the depth of penetration of a fabric treatment component in the fabric conditioning step.

14. The method according to claim 10 wherein the fabric treatment step is an aqueous fabric treatment step.

15. The method according to claim 10 wherein the fabric treatment step is an aqueous fabric treatment step comprising a fabric washing step.

16. The method according to claim 10 wherein the first image comprises fabric and a soil.

17. The method according to claim 10 wherein the fabric is treated with a fabric conditioning component.

18. The method according to claim 10 wherein the imaging device is a magnetic resonance imaging machine.

19. The method according to claim 10 wherein the imaging device comprises an X-ray machine.

20. The method according to claim 10 wherein the imaging device uses computed tomography, micro or nano-CT tomography.
